(19) United States
(12) Patent Application Publication
(10) Pub. No.: US 2013/0134309 A1
(43) Pub. Date: May 30, 2013

(54) NONLINEAR OPTICAL AND ELECTRO-OPTICAL DEVICES AND METHODS OF USE THEREOF FOR AMPLIFICATION OF NON-LINEAR PROPERTIES

(71) Applicant: Yissum and Research Development Company of t, Jerusalem (IL)

(72) Inventor: Ronen RAPAPORT, Tel Aviv (IL)

(73) Assignee: Yissum and Research Development Company of the Hebrew University of Jerusalem LTD., Jerusalem (IL)

(21) Appl. No.: 13/674,172

(22) Filed: Nov. 12, 2012

Related U.S. Application Data
(60) Provisional application No. 61/558,061, filed on Nov. 10, 2011.

(51) Int. Cl. G02F 1/355; H01L 27/146; H01L 31/0232

(52) U.S. Cl. CPC G02F 1/3556; H01L 31/0232; H01L 27/14625; Y10S 977/774; B82Y 20/00
USPC 250/330; 250/216; 250/225; 250/338.1; 257/432; 250/338.4; 359/332; 977/774

(57) ABSTRACT

This invention provides devices and methods for broad-band amplification of non linear properties. This invention provides devices comprising optically non linear material that is in contact with a slit array. The slit array causes enhancement of the electromagnetic field within the non linear materials. The enhancement of the electromagnetic field within the optically non linear material results in an amplified non linear response exhibited by the optically non linear materials. This invention provides detectors and imaging systems based on devices and methods of this invention.

### CROSS REFERENCE TO RELATED APPLICATIONS

This application claims the benefit of U.S. Provisional Application Ser. No. 61/558,061, filed Nov. 10, 2011, which is hereby incorporated by reference in its entirety.

### FIELD OF THE INVENTION

This invention provides devices and methods for amplification of non-linear properties.

### BACKGROUND OF THE INVENTION

Non-linear materials are materials in which the dielectric polarization P responds nonlinearly to the electric field E of light. Non linear properties of materials are exhibited when light irradiates the material. The light emitted by the material upon irradiation will posses different properties when compared to the incoming light. For example, second harmonic generation is a non linear property wherein the frequency of light emitted by the non-linear material can be two times the frequency of the light irradiating the material. Other non linear phenomena include third harmonic generation, stimulated Raman scattering, and self-focusing.

In order to observe non linear behavior of materials, strong light intensities such as those provided by lasers must be provided. For some materials for which the laser intensity is not sufficient and for some applications for which lasers can not be employed, non-linear optical phenomenon may be lost.

### SUMMARY OF THE INVENTION

In one embodiment, this invention is directed to optical and to electro-optical devices comprising a grating of slit array, and one or more dielectric layers, wherein said layers comprise non linear material and said layers are positioned on top of said grating, below said grating or on top and below said grating. In one embodiment, the design of the slit array and the design of the dielectric layer(s) enables enhancement of the electromagnetic field within the dielectric layer(s). In one embodiment, the enhancement of the field augments non linear phenomenon within the dielectric material which results in enhancement of an optical signal and/or enhancement of an electric signal generated within the dielectric material.

In one embodiment, this invention provides an optical device comprising a grating, said grating comprising a slit array, and one or more dielectric layers, wherein at least one of said layers comprise non linear material and said layers are positioned on top of said grating, below said grating or on top and below said grating and wherein said layer(s) has no significant linear absorption at a certain wavelength range of the electromagnetic radiation spectrum.

In one embodiment, the dielectric layers comprise GaAs, AlGaAs, Si, silicon dioxide, Quartz, Ge, GaN, GaAlN, InGaAs, InGaP or a combination thereof.

In one embodiment, this invention provides a method of amplification of an electromagnetic intensity within layered non-linear material resulting in amplification of non-linear signals, said method comprising:

a. providing an optical device comprising:

a grating comprising a slit array, and one or more dielectric layers, wherein at least one of said layers comprise non linear material and said layers are positioned on top of said grating, below said grating or on top and below said grating and wherein said layer(s) has no significant linear absorption at a certain wavelength range of the electromagnetic radiation spectrum;

b. irradiating said optical device with an electromagnetic radiation at said wavelength range or portions thereof; and

c. collecting and/or measuring electromagnetic radiation emitted from said optical device, wherein said radiation comprising a non linear signal;

wherein upon said irradiation of said optical device, the electromagnetic intensity within said layered optically non-linear material is enhanced resulting in amplification of said non-linear signal.

In one embodiment, this invention provides a method of IR light sensing, said method comprising:

a. providing an optical device comprising:

a grating of a slit array and one or more dielectric layers, wherein at least one of said layers comprise non linear material and said layers are positioned on top of said grating, below said grating or on top and below said grating and wherein said layer(s) has no significant linear absorption at a certain IR wavelength range of the electromagnetic radiation spectrum;

b. providing an optical detector sensitive to visible light;

c. using said detector for collecting and/or measuring visible electromagnetic radiation emitted from said optical device.

In one embodiment, the radiation emitted from the optical device is the result of an IR two photon absorption process occurring within the dielectric layers followed by visible fluorescence.

In one embodiment, this invention provides a method of IR imaging, said method comprising:

a. providing an array of optical devices, wherein each optical device comprising:

a grating of a slit array, and one or more dielectric layers, wherein said layers comprise non linear material and said layers are positioned on top of said grating, below said grating or on top and below said grating and wherein said layer(s) has no significant linear absorption at a certain IR wavelength range of the electromagnetic radiation spectrum;

b. providing optical detectors sensitive to visible light such that each detector addresses one of said optical devices;

c. using said detectors for collecting and/or measuring electromagnetic radiation emitted from each of said optical devices; and

d. compiling an image from said electromagnetic radiation emitted from each of said optical devices.

In one embodiment, this invention provides an electro-optical device comprising a grating of a slit array and a PN junction, a PIN junction or an avalanche photo diode, wherein said PN junction, said PIN junction or said avalanche photo diode is positioned on top of said grating, below said grating or on top and below said grating and wherein said PN junction, said PIN junction or said avalanche photo diode has no significant linear absorption at a certain wavelength range of the electromagnetic radiation spectrum, and wherein said PN junction, said PIN junction or said avalanche photo diode generates electron-hole pairs upon non-linear absorption of electromagnetic radiation at said wavelength range and wherein an electrical current is generated by said electron-hole pairs.

In one embodiment, the device further comprises a current meter connected to said PN junction, said PIN junction or to said avalanche photo diode.

In one embodiment, the device further comprise a power supply connected to said PN junction, said PIN junction or to said avalanche photo diode.

In one embodiment, the PN junction, said PIN junction or said avalanche photo diode comprise GaAs, AlGaAs, Si, silicon dioxide, Quartz, Ge, GaN, GaAlN, InGaAs, InGaP or a combination thereof.

In one embodiment, the non linear absorption is two-photon absorption. In one embodiment, the electron-hole pair is generated by absorption of radiation at the IR, the near IR and/or at the visible electromagnetic range.

In one embodiment, this invention provides a method of detection of electromagnetic radiation, said method comprising:

a. providing an electro-optical device comprising:

a grating comprising a slit array and a PN junction, a PIN junction or an avalanche photo diode, wherein said PN junction, said PIN junction or said avalanche photo diode is positioned on top of said grating, below said grating or on top and below said grating and wherein said PN junction, said PIN junction or said avalanche photo diode has no significant linear absorption at a certain wavelength range of the electromagnetic radiation spectrum;

b. connecting said PN junction, said PIN junction or said avalanche photo diode to a current meter;

d. irradiating said electro-optical device with electromagnetic radiation at said certain wavelength range such that said PN junction, said PIN junction or said avalanche photo diode generates electron-hole pairs upon non-linear absorption of said electromagnetic radiation at said wavelength range and wherein an electrical current is generated by said electron-hole pairs; and

e. using said current meter for detecting and/or measuring said current;

wherein upon said irradiation of said electro-optical device, the electromagnetic intensity within said PN junction, said PIN junction or said avalanche photo diode is enhanced resulting in amplification of a two-photon absorption process followed by amplified current generation by said PN junction, said PIN junction or said avalanche photo diode.

In one embodiment, the PN junction, a PIN junction or an avalanche photo diode is connected to a power supply. In one embodiment, the power supply is used to apply voltage to said PN junction, a PIN junction or an avalanche photo diode. In one embodiment, the PN junction, said PIN junction or said avalanche photo diode comprise GaAs, AlGaAs, Si, silicon dioxide, Quartz, Ge, GaN, GaAlN, InGaAs, InGaP or a combination thereof.

In one embodiment, the certain wavelength range is within the IR range. In one embodiment, the non linear absorption is two-photon absorption. In one embodiment, the electron-hole pair is generated by absorption of electromagnetic radiation in the near IR range, in the visible range or a combination thereof.

In one embodiment, the intensity of the absorbed radiation within the device ranges between 10 and 100 times the intensity of said irradiated electromagnetic radiation.

In one embodiment, this invention provides a method of IR light sensing, said method comprising:

a. providing an electro-optical device comprising:

a grating comprising a slit array and a PN junction, a PIN junction or an avalanche photo diode, wherein said PN junction, said PIN junction or said avalanche photo diode is positioned on top of said grating, below said grating or on top and below said grating and wherein said PN junction, said PIN junction or said avalanche photo diode has no significant linear absorption at a certain wavelength range of the electromagnetic radiation spectrum, and wherein said PN junction, said PIN junction or said avalanche photo diode generates electron-hole pairs upon non-linear absorption of electromagnetic radiation at said wavelength range and wherein an electrical current is generated by said electron-hole pairs;

b. connecting said dielectric material to a current meter;

c. using said current meter for detecting and/or measuring current generated by said electro-optical device;

wherein upon IR sensing by said electro-optical device, the IR electromagnetic intensity within said PN junction, a PIN junction or an avalanche photo diode is enhanced resulting in amplification of IR two-photon absorption process within said PN junction, a PIN junction or an avalanche photo diode followed by amplified current generation by said PN junction, a PIN junction or an avalanche photo diode.

In one embodiment, the PN junction, a PIN junction or an avalanche photo diode is connected to a power supply. In one embodiment, the power supply is used to apply voltage to said PN junction, a PIN junction or an avalanche photo diode.

In one embodiment, the IR light is generated by a laser, by a light emitting diode or by an object.

In one embodiment, this invention provides a method of IR imaging, said method comprising:

a. providing an array of electro-optical devices, wherein each electro-optical device comprising:

a grating comprising a slit array and a PN junction, a PIN junction or an avalanche photo diode, wherein said PN junction, said PIN junction or said avalanche photo diode is positioned on top of said grating, below said grating or on top and below said grating and wherein said PN junction, said PIN junction or said avalanche photo diode has no significant linear absorption at a certain wavelength range of the electromagnetic radiation spectrum, and wherein said PN junction, said PIN junction or said avalanche photo diode generates electron-hole pairs upon non-linear absorption of electromagnetic radiation at said wavelength range and wherein an electrical current is generated by said electron-hole pairs;

b. providing electrical current detectors such that each detector addresses one of said electro-optical devices;

c. using said current detectors for collecting and/or measuring current generated by each of said electro-optical devices; and

d. compiling an image from said current generated by each of said electro-optical devices.

In one embodiment, the PN junction, said PIN junction or said avalanche photo diode is connected to a power supply. In one embodiment, power supply is used to apply voltage to said PN junction, said PIN junction or said avalanche photo diode.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 (a) is a schematic of the experimental setup: a nanoslit array (NSA) structure depicted in the center consists of a dielectric polymer layer with nanocrystal quantum dots (NQD's) (marked by circles) on top of an aluminum (Al) grating. The excitation pulse refers to the exciting NIR pulse while the emission pulse refers to the upconversion light emitted from the NQD's. The NSA sample dimensions are given by: a=slit width, d=NSA periodicity, h=Aluminum height, H=width of the polymer layer comprising the NQD's. (b) The absorption (dashed line) and emission (full line) spectra of the NQD's along with the spectral range of the laser excitation wavelengths (box with large arrow). (c) An energy level scheme of two photon absorption (TPA) and the resulting upconversion process. The up-pointing arrows correspond to the two photons absorbed, the diagonally-down arrow corresponds to the non-radiative decay to the first exitonic transition and the down-pointing arrow is the induced upconverted photon.

FIG. 2 demonstrates two photon absorption induced fluorescence. The samples were irradiated between 1400-1600 nm. The reference is an identical sample without the metal grating.

FIG. 3 illustrates a configuration of a polymer comprising quantum dots on top of a nano-slit array. The nano slit array is mounted on a glass substrate.

FIG. 4 illustrates TPA (two photon absorption) and induced upconverted fluorescence in semiconductor NQDs in TE (transverse electric) polarization in metallic nanoslit arrays with a maximal enhancement of ˜400; the amplification of the non-linear signals occurs within the dielectric layer(s) of the nano-slit array.

FIG. 5 is a logarithmic scale of I_{UC} at an excitation wavelength of 1505 nm. The upconversion due to TPA is evident as the slope≅2, indicating that I_{UC}∝I² using the setup of FIG. 1a (I_{UC} means I upconversion).

FIG. 6 is: (a) enhancement measurement with an excitation at 1500 nm in TM (transverse magnetic) polarization. The dashed blue curve corresponds to I_{UC} from the investigated NSA sample while the green curve corresponds to the reference sample (A reference sample is an identical sample without the grating). (b) γ²exp as a function of the laser peak power showing that γ²exp is power independent. Using the setup of FIG. 1a.

FIG. 7 is the measured enhancement (γ²exp) for (a) TM polarization and (b) TE polarization is shown by the dots as a function of the excitation wavelength (with a dashed line as a guide to the eye). The transmission spectra from the respective NSA is shown by the top dotted continuous (blue) curves. The circles present the wavelengths used for the calculations in FIG. 8.

FIG. 8 is: (a) and (c)—calculated and experimental transmission spectra for TE and TM polarizations, respectively. (b) and (d)—calculated near-field intensities for the wavelengths indicated in FIG. 8 by circles for TE and TM polarizations respectively. The borders between the different layers of the unit cell are indicated by the white lines and the dashed lines represent the location of the slit.

FIG. 9 is: γcalc as a function of the excitation wavelength using the setup of FIG. 1. The lined curve corresponds to the calculated average enhancement in TE polarization showing a very narrow peak (˜3 nm wide) at 1466 nm. The dashed curve corresponds to TM polarization where the magnitude is much lower than in TE polarization (peak value of ˜1.8 at 1505 nm) with a width larger than 50 nm.

FIG. 10 is the experimental (dots) and the calculated (squares) enhancement factor as a function of the excitation wavelength (the dashed lines are a guide to the eye) for (a)—TE polarization, (b)—TM polarization using the setup of FIG. 1a.

FIG. 11 illustrates (a) Near IR to visible optical up-converter and a detector and (b) NIR GaAs or Si-based detector.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

In recent years, a new family of optical structures for the manipulation of light has been studied. This family includes subwavelength metallic structures and more specifically, metallic nanoslit array (NSA) structures. NSA's are composed of metal transmission gratings with very narrow slits. Such structures have been predicted and later shown to exhibit a phenomenon known as extraordinary transmission (EOT), in which, under certain resonant wavelength regimes, light can be transmitted in an almost perfect way through these gratings. This almost perfect transmission occurs even when the slits are much smaller than the impinging light wavelength. One explanation of the exact mechanism behind this effect is that these resonances correspond to standing waves in the vicinity of the NSA.

One of the challenges in obtaining non-linear response from materials is that the intensity of the electromagnetic radiation that is used to excite the material must be very high. In one embodiment, this invention provides slit arrays in order to enhance the electromagnetic field within the non linear material. Such enhancement results in an amplified non linear response of the materials.

In one embodiment, this invention uses slit arrays to enhance the electromagnetic radiation in optically non linear materials. In one embodiment, this invention combines slit arrays with optically non linear materials in order to enhance the electromagnetic field within the non linear material. The enhanced electromagnetic field within the non linear material, give rise to measurable non linear optical behavior or to a measurable electrical signal. In one embodiment, low non-linear response of materials is augmented by using slit arrays in conjunction with the material. In one embodiment, the slit array enhances the electromagnetic field within the optically non linear material such that non linear phenomenon obtained by such material is amplified or enhanced. In one embodiment, the combination of the optically non linear material and the slit array yields non linear response that could not be detected or measured without the addition of the slit array.

In one embodiment, this invention is directed to an optical device comprising a grating, said grating comprising a slit array, and one or more dielectric layers, wherein said layers comprise non linear material and said layers are positioned on top of said grating, below said grating or on top and below said grating and wherein said layer(s) has no significant linear absorption at a certain wavelength range of the electromagnetic radiation spectrum.

In one embodiment, the one or more dielectric layers is in contact with the slit array.

In one embodiment, this invention is directed to a method of amplification of an electromagnetic intensity within layered non-linear material resulting in amplification of non-linear signals; said method comprising:

a. providing an optical device comprising:

a grating comprising a slit array and one or more dielectric layers, wherein said layers comprise non linear material and said layers are positioned on top of said grating, below said grating or on top and below said grating and wherein said layer(s) has no significant linear absorption at a certain wavelength range of the electromagnetic radiation spectrum;

b. irradiating said optical device with an electromagnetic radiation at said wavelength range or portions thereof; and

c. collecting and/or measuring electromagnetic radiation emitted from said optical device, wherein said radiation comprising a non linear signal;

wherein upon said irradiation of said optical device, the electromagnetic intensity within said layered optically non-linear material is enhanced resulting in amplification of said non-linear signal.

In one embodiment, the device of this invention and methods of use thereof refer to an optical device that exhibits an optical response. In one embodiment, an optical device is a device that is sensitive to electromagnetic radiation. In one embodiment, an optical device is a device that transmits, absorbs or reflects electromagnetic radiation. In one embodiment, an optical device transmits and/or absorbs and/or reflects electromagnetic radiation. In one embodiment, the response of an optical device to electromagnetic radiation is linear. In one embodiment, the response of the optical device to EM radiation is non linear. In one embodiment, the response of the optical device to electromagnetic (EM) radiation is at least one of the following response: a change in the wavelength of the radiation, a change in angle/direction of the radiation, absorbance of a portion or of all of the radiation, transmission of a portion of or of all of the radiation, reflectance of the radiation in a direction opposite to the radiation irradiated onto the device. Reflectance in an angle different than zero degrees as compared to the angle of radiation irradiated onto the device; diffraction, amplification, enhancement of EM signal, concentration or divergence of radiation, frequency/wavelength modification, amplitude modification, directional change, and the conversion of EM radiation to EM radiation of different frequencies, heat, electricity or to a mechanical effect.

In one embodiment, the device and methods of this invention comprise dielectric layers. In another embodiment, the dielectric layers comprise a dielectric material. In another embodiment, the dielectric material comprises a non linear material. In one embodiment, non linear material or non linear media is a media in which the dielectric polarization P responds nonlinearly to the electric field E of the light. In one embodiment, nonlinear optical phenomena include for example second harmonic generation, or third order nonlinear effects.

In one embodiment, the device of this invention and methods of use thereof comprises a non-linear material. In one embodiment the non-linear material is a transparent organic material.

In one embodiment, the device of this invention and methods of use thereof comprises a non-linear material. In one embodiment, the non-linear material comprises quantum dots. In one embodiment, the non-linear material comprises quantum dots embedded in organic material. In one embodiment, the non linear material comprises a polymer embedded with quantum dots. In one embodiment a quantum dot (QD) is a material with very small geometrical dimensions. For example, the diameter of a ball-shaped quantum dot is in the nanometer or the micrometer range. In one embodiment, the dimension of a quantum dot is around 100 nm. In one embodiment, the dimension of a quantum dot ranges between 1 nm and 500 nm. Because of their small size, optical and electronic properties of QD's are different from bulk properties of the same material. The electrical/optical properties of QD's depend on their size, and accordingly, devices and systems can be designed by tuning the size and the materials of the QD's employed in the device. In one embodiment, quantum dot can be of any shape including but not limited to a ball, a cube, a pyramid, a non-symmetrical geometrical shape, a rod, a cylinder, hexagon, elliptical shape etc.

In one embodiment, the non-linear material comprises quantum dots. In one embodiment, the quantum dots comprise CdSe. In another embodiment, the quantum dots comprise InAs. In one embodiment, the quantum dots are core-shell quantum dots. In one embodiment, core-shell QD's are QD's wherein the core is made of one material and the shell is made of a different material. In one embodiment the core-shell QD's comprise a core of InAs and a shell of CdSe. In one embodiment, the QD's are nanocrystalline. In one embodiment, at least a portion of the QD's is crystalline. In another embodiment, the quantum dots comprise InAs, CdSe, PbS, PbSe, CdTe Ge, Si, GaAs, InGaAs or a combination thereof.

In one embodiment, the dielectric material of this invention is positioned as one or more layers on top of the grating, below the grating or on top and below the grating. In one embodiment, the layers comprise dielectric materials. In one embodiment, the dielectric materials include non limiting examples of GaAs, AlGaAs, silicon, silicon dioxide, Quartz, Ge, GaN, GaAlN, InGaAs or InGaP. In one embodiment, dielectric materials are known to a person of ordinary skill in the art. In one embodiment, not all the layers include non-linear material. In one embodiment, the layers comprise silicon, silicon oxide. In one embodiment, non limiting examples of non-linear material include BBO (β-barium borate), KDP (potassium dihydrogen phosphate), KTP (potassium titanyl phosphate), silicon, silicon oxide and lithium niobate.

The device of this invention provides much greater flexibility in having the possibility to place the nonlinear material in different layers and not directly only into the slits. In one embodiment, the non linear material is further positioned within the slits of the grating.

In one embodiment, the device and methods of this invention comprises a substrate. In one embodiment, this invention provides a substrate on which or within which the gratings are positioned. In one embodiment, the dielectric layers are positioned on top of the grating and the grating is positioned on a substrate. In some embodiments, the term “substrate” is to be understood to comprise a single material or multiple layers of materials, with, in some embodiments, such layers imparting desired characteristics to the device, or to aid in its to mounting and/or its operation. In one embodiment, a substrate is the support provided for the gratings. In one embodiment, the substrate provides the surface on which the gratings are constructed.

In one embodiment, device and methods of this invention comprise a substrate. In one embodiment, the substrate is or comprises glass. In one embodiment, the substrate of this invention comprises silicon. In one embodiment the substrate is comprised of silicon covered by a layer of silicon oxide or silicon nitride. In one embodiment the substrate is comprised of doped silicon. In one embodiment the substrate comprises a polymer. In one embodiment the polymer is PDMS. In one embodiment, the substrate comprises a ceramic material.

In one embodiment, the substrate and/or other components of the device can be made from a wide variety of materials including, but not limited to, silicon, silicon dioxide, silicon nitride, glass, doped glass, fused silica, gallium arsenide, indium gallium arsenide, indium phosphide, III-V materials, silicone rubber, aluminum, ceramics, polyimide, quartz, plastics, resins and polymers including polymethylmethacrylate (PMMA), acrylics, polyethylene, polyethylene terephthalate, polycarbonate, polystyrene and other styrene copolymers, polypropylene, polytetrafluoroethylene, superalloys, zircaloy, steel, gold, silver, copper, tungsten, molybdeumn, tantalum, KOVAR, KEVLAR, KAPTON, MYLAR, teflon, brass, sapphire, other plastics, or other flexible plastics (polyimide), ceramics, etc., or a combination thereof. The substrate may be ground or processed flat. High quality glasses such as high melting borosilicate or fused silicas may be used, in some embodiments, for their UV transmission properties when any of the sample manipulation and/or detection steps require such light based technologies. In addition, as outlined herein, portions of the internal and/or external surfaces of the device may be coated with a variety of coatings as needed, as will be appreciated by the skilled artisan.

In one embodiment the substrate is comprised of a membrane. In one embodiment the membrane is a silicon nitride membrane.

In one embodiment the substrate is comprised of a transparent material. In one embodiment the transparent material is glass, quartz or a polymer. In one embodiment the substrate is rigid. In one embodiment the substrate is flexible. In one embodiment, substrate integrity is not compromised by corrosive materials or organic solvents. In one embodiment the substrate and the oxide layer of the substrate are stable such as silicon oxide on silicon.

In one embodiment, the device of this invention and methods of this invention comprise a grating.

In one embodiment, the grating can be constructed by lithographic methods, by UV or e-beam lithography, by soft lithography, by using a stamp, a mold, a mask, a scanning tip, a template, deposition and etching, CVD, vacuum deposition, evaporation, electro-deposition or any other construction method as known to a person of ordinary skill in the art.

In one embodiment, the grating can be grown (or deposited) on top of a desired pre-made dielectric layer stack made by any method (thermally/epitaxially deposited or evaporation/sputtering/spin-on). In one embodiment, the thin dielectric layer/layers can be grown (thermally/epitaxially) or deposited (evaporation/sputtering/spin-on) on top of a grating on a given dielectric substrate. In one embodiment, the grating can be grown (or deposited) on top of a desired pre-made dielectric layer stack and dielectric layer/layers can be grown/deposited on to top of the grating.

In one embodiment, the grating is an array of blocks separated by slits. In one embodiment the grating is an array of elongated elements that are periodically spaced. In one embodiment, a grating is a regularly spaced array of identical, parallel, elongated elements. In one embodiment, the grating is of rectangular structures regularly spaced. In one embodiment, the grating is a structure comprising rectangular blocks that are assembled on a surface such that there is constant spacing between any two blocks in a row and a constant spacing between any two block in a column. In one embodiment, the grating is a slit array. In one embodiment, the grating is a nano-slit array. In one embodiment, the grating is a micro-slit array.

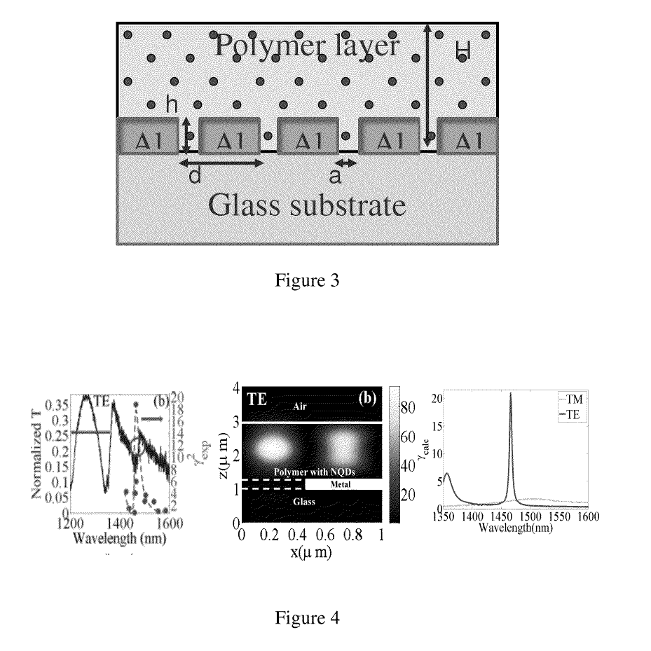

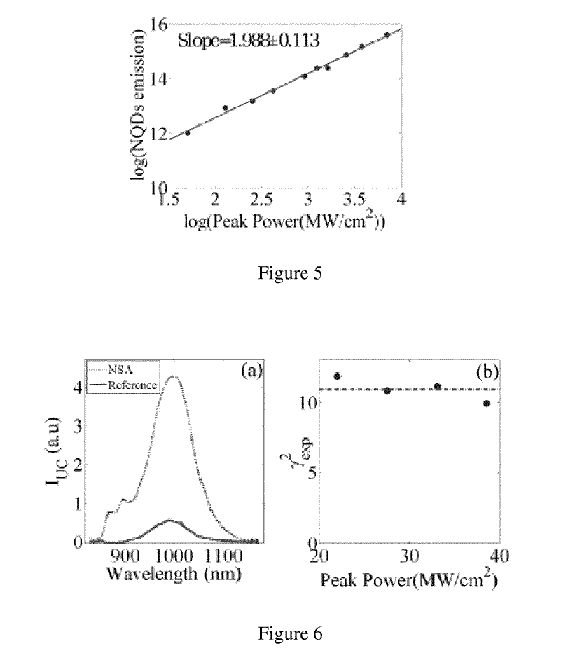

In one embodiment, the two longest axes of the grating are the axes defining the plane on which the grating is formed. In one embodiment, the grating covers a large surface and the height of each feature of the grating is smaller than the length of each feature. The height of each block of the grating (“h”, FIG. 3) is much smaller than the length/width of the complete grating structure. The grating can be viewed as a close to a “two-dimensional” structure, wherein the plane comprising the grating structure array defines the two dimensions of the grating. In one embodiment, the two longest axes of the grating are the length and the width of the grating array. The shortest axis of the grating is the height of the structures forming the array.

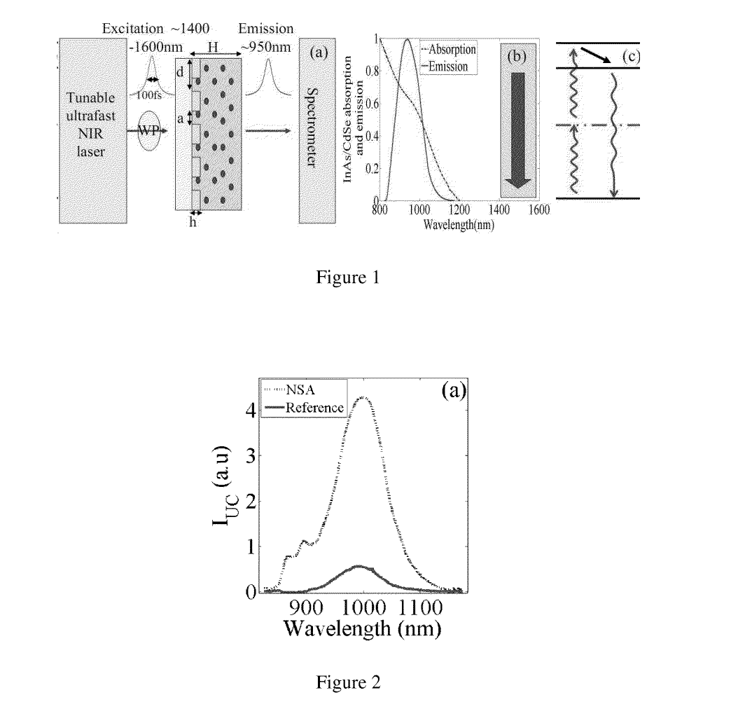

In one embodiment, the grating of this invention comprises an array of blocks separated by slits (FIG. 3 and FIG. 1a). In one embodiment, the width (“d-a” in FIG. 3) of said blocks ranges between 10 nm and 1500 nm. In one embodiment, (“d-a”) refers to (“d minus a”). In one embodiment, “d-a” refers to the period minus the width of the slit. In one embodiment, the width (“d-a” in FIG. 3) of said blocks ranges between 100 nm and 750 nm. In one embodiment, the width (“d-a” in FIG. 3) of said blocks ranges between 100 nm and 10,000 nm. In one embodiment, the width of said slits ranges between 200 nm and 500 nm. In one embodiment, the width (“d-a” in FIG. 3) of said blocks ranges between 400 nm and 800 nm. In one embodiment, the width of said blocks ranges between 300 nm and 700 nm. In one embodiment, the width of said blocks ranges between 200 nm and 500 nm. In one embodiment, the width (“d-a” in FIG. 3) of said blocks ranges between 400 nm and 600 nm. In one embodiment, the width of the blocks is constant. In one embodiment, the width of the blocks varies. In one embodiment, the width of the slits is constant. In one embodiment, the width of the slits varies. In one embodiment, the block/slit structure is tapered.

In one embodiment, the width of said slits (“a” in FIG. 3) ranges between 10 nm and 1000 nm. In one embodiment, the width of said slits (“a” in FIG. 3) ranges between 300 nm and 500 nm. In one embodiment, the width of said slits ranges between 10 nm and 200 nm. In one embodiment, the width of said slits ranges between 100 nm and 500 nm. In one embodiment, the width of said slits ranges between 300 nm and 500 nm. In one embodiment, the width of said slits ranges between 150 nm and 400 nm. In one embodiment, the width of said slits ranges between 100 nm and 750 nm. In one embodiment, the width of said slits is in the nanometer range. In one embodiment, the width of said slits is in the micrometer range. In one embodiment, the width of the slits is constant. In one embodiment, the width of the slits varies. In one embodiment, a=350 nm. In one embodiment, a=450 nm.

In one embodiment, the period of blocks (“d” in FIG. 3) ranges between 10 nm and 1000 nm. In one embodiment, the period of blocks (“d” in FIG. 3) ranges between 100 nm and 10000 nm. In one embodiment, the period of blocks ranges between 200 nm and 500 nm. In one embodiment, the period of blocks ranges between 400 nm and 800 nm. In one embodiment, the period of blocks ranges between 500 nm and 1000 nm. In one embodiment, d=1 μm. In one embodiment, d=0.8 μm.

In one embodiment, the height (“h” in FIG. 3) of said blocks ranges between 10 nm and 500 nm. In one embodiment, the height of said blocks ranges between 10 nm and 1500 nm. In one embodiment, the height of said blocks is approximately 250 nm.

In one embodiment, the grating comprises metal. In one embodiment, the metal is aluminum. In one embodiment, the metal is gold. In one embodiment, the metal is any metal that can be used to form the grating. In one embodiment, the metal is selected from the group consisting of: Au, Ag, Ti, Al, Cu, Cr, Ni, Fe, Pt or Pd or a combination thereof. In one embodiment, the grating comprises a metal alloy. In one embodiment, the grating comprises a coated metal. In one embodiment, the coating comprises the optically non linear material. In one embodiment, the coating of the metallic grating comprises quantum dots or quantum dots embedded in a polymer. In one embodiment, the grating is coated by a mixture of quantum dots and non linear material. In one embodiment, the coating is the dielectric layers. In another embodiment, the coating comprises quantum dots embedded in a polymer.

In one embodiment, methods of this invention comprise irradiation of devices of the invention with an electromagnetic radiation. In one embodiment, methods of this invention comprise broad band radiation. In one embodiment, broad band represents a large range of frequencies. In one embodiment, broad band refers to a signal that comprises more than a single wavelength. In one embodiment, broad band reflects a signal of greater bandwidth, as compared with another relevant signal. In one embodiment, broad band means a spectrum of wavelengths that are transmitted from a source or received by a device or a detector. In one embodiment, broad band refers to a relatively wide range (or band) of frequencies. In one embodiment, broad band is a relative term, and can be compared to a certain narrow band signal. In one embodiment, broad band of frequencies can be the frequency range between 1400 nm-1600 nm. In one embodiment, the broad-band radiation ranges between 1200 nm and 1600 nm. In one embodiment, the broad-band radiation ranges between 1000 nm and 2000 nm.

In one embodiment, the irradiated electromagnetic radiation is in the IR range. In one embodiment, the irradiated electromagnetic radiation is in the near IR range. In one embodiment, the irradiated electromagnetic radiation is NIR. In one embodiment, the irradiated electromagnetic radiation is broad-band. In one embodiment, the emitted electromagnetic radiation (emitted form devices of the invention) is in the near IR range. In one embodiment, the emitted electromagnetic radiation is in the visible range. In one embodiment, a broad band of frequencies may be a band that includes portions of the IR range. In one embodiment, a broadband of frequencies may be a band that includes parts of the UV and/or the visible range of the electromagnetic radiation.

The non linear phenomenon exhibited by devices of the invention may be for incoming radiation of any frequency. In one embodiment, devices of the invention exhibit a non-linear response for incoming radiation in the IR, visible, UV, or any other range of the electromagnetic radiation. In one embodiment, any wavelength of incoming light may undergo two-photon absorption within at least one of the dielectric layers in the device and can generate a photon of shorter wavelength. Accordingly, methods and optical devices of this invention are applicable to any wavelength and any wavelength range of incoming radiation.

In one embodiment, any wavelength of incoming light may undergo two-photon absorption within at least one of the dielectric layers in the device and can generate an electron-hole pair. Accordingly, methods and electro-optical devices of this invention are applicable to any wavelength and any wavelength range of incoming radiation.

In one embodiment, the incoming radiation that reaches the device is in the near IR range and the radiation that is emitted by the device is at the visible range.

In one embodiment, the majority of the emitted electromagnetic radiation is at a specific wavelength. In one embodiment, the specific wavelength is 800 nm.

In one embodiment, the irradiated electromagnetic (EM) radiation, the emitted EM radiation or a combination thereof are perpendicular to the plane comprising the two longest axes of said grating.

In one embodiment, the irradiated EM radiation, the emitted EM radiation or a combination thereof are not perpendicular to the plane comprising the two longest axes of said grating. In one embodiment, the irradiated EM radiation, the emitted EM radiation or a combination thereof is polarized. In one embodiment, the irradiated EM radiation, said emitted EM radiation or a combination thereof is linearly polarized.

In one embodiment, the irradiated EM radiation is irradiated from a radiation source. In one embodiment, the radiation source is a Ti:Sapphire laser. In one embodiment, the irradiated EM radiation is irradiated continuously. In one embodiment, the irradiated EM radiation is pulsed.

In one embodiment, the time of said pulses ranges between 20 fs and 200 fs. In one embodiment, the time of said pulses is in the sub-100 fs range.

In one embodiment, methods of this invention comprise irradiating a device of this invention. In one embodiment, irradiating a device or a target means exposing the device/target to the irradiated radiation. In one embodiment, the term “irradiating” is related to the irradiation of a device/target with EM radiation, EM radiation, light, a frequency/wavelength range, a single or narrow or broad band wavelength/frequency etc. Irradiating a device/target can be done using any radiation source such as a lamp or a laser or a thermal radiation source. In one embodiment, the environment or the atmosphere or objects therein may serve as the irradiation source for a device.

In one embodiment, the device is irradiated by an un-polarized light. In another embodiment, un-polarized light comprises light waves possessing electric field vectors in all perpendicular planes with respect to the direction of propagation of the light. When the electric field vectors are restricted to a single plane, the light is said to be polarized with respect to the direction of propagation of the light.

In one embodiment, the device is irradiated by TE (Transverse Electric) polarized light. In another embodiment, TE polarized light is characterized by its electric field being perpendicular to the plane of incidence. For TE light, the magnetic field lies in the plane of incidence. the device is irradiated by TM (Transverse Magnetic) polarized light. In one embodiment, TM (Transverse Magnetic) polarized light is characterized by its magnetic field being perpendicular to the plane of incidence. For TM light, the electric field lies in the plane of incidence.

In one embodiment, the size of the area illuminated by said irradiated EM radiation ranges between 0.0001 cm and 1 cm within the layered non-linear material.

In one embodiment, the device of this invention and methods of use thereof provides enhancements in both TE and TM polarization simultaneously.

In one embodiment, the methods of this invention comprising collecting and/or measuring electromagnetic radiation emitted from said optical device. In one embodiment, collecting means receiving the radiation emitted by the device. In one embodiment, collection is done by EM detectors. In one embodiment, radiation emitted by the device is received by a detector that may detect the frequencies and/or the amplitudes of the received radiation.

In one embodiment, measuring the emitted frequency from a device means to evaluate the spectral characteristics of the emitted radiation. In one embodiment, measuring means evaluating the emitted spectrum of the light. In one embodiment, measuring means evaluating the emitted wavelengths and the intensity of the emission in each wavelength. In one embodiment, measuring means obtaining a spectrum. In one embodiment, a spectrum shows the intensity of the emitted light at each frequency/wavelength. In one embodiment, radiation emitted by the device is detected. In one embodiment, detection means detection of radiation at a certain wavelength or at a certain wavelength range. Radiation is detected if the intensity of the radiation is above a certain threshold in one embodiment.

In one embodiment, the emitted electromagnetic radiation is in the near IR range. In one embodiment, the majority of the emitted electromagnetic radiation is at a specific wavelength. In one embodiment, the specific wavelength is 800 nm. In one embodiment, the irradiated EM radiation, the emitted EM radiation or a combination thereof are perpendicular to the plane comprising the two longest axes of said grating. In one embodiment, the irradiated EM radiation, the emitted EM radiation or a combination thereof are not perpendicular to the plane comprising the two longest axes of said grating. In one embodiment, the emitted radiation is in the visible range.

In one embodiment, the electromagnetic radiation emitted from devices of this invention is a result of a two photon absorption (TPA) process. In one embodiment, two photon absorption by a material results in upconversion of the radiation. In one embodiment, the radiation emitted by the material is of a higher frequency than the radiation absorbed from a single photon. In one embodiment, absorption of two photons by the material results in an excited energy state that reflects the combined energy of the two photons. Upon non-radiative decay to the first excitonic transition, an induced upconverted photon is emitted from the material (see FIG. 1c). The energy of such photon is higher than the energy of the photons absorbed by the material. In one embodiment, electromagnetic radiation is emitted from optical devices of the invention, wherein the radiation comprising a non linear signal. In one embodiment, the non-linear signal in devices and methods of the invention is the result of a two-photon absorption (TPA) process.

In one embodiment, the electromagnetic radiation emitted from the device of this invention is a result of second harmonic generation (SHG). In one embodiment, electromagnetic radiation is emitted from optical devices of the invention, wherein the radiation comprising a non linear signal. In one embodiment, the non-linear signal is a result of a second harmonic generation (SHG) process. In one embodiment, second harmonic generation (SHG) is a nonlinear optical effect in which a nonlinear material emits photons of twice the energy, and therefore twice the frequency and half the wavelength of the photons to which the material was exposed. SHG is a special case of sum frequency generation.

In one embodiment, the intensity within the device ranges between 10 and 100 times the irradiated electromagnetic intensity. This amplification would not be observed from the nonlinear material without the grating. In one embodiment, γ² ranges between 20 and 50,000. In one embodiment, the average γ² is 8000. In one embodiment γ² is up to 23,000.

In one embodiment, γ² ranges between 20 and 10,000. In one embodiment, γ² ranges between 20 and 50,000. In one embodiment, γ² ranges between 5000 and 10,000. In one embodiment, γ² is 8000. In one embodiment, γ² is 23,000.

In one embodiment, the wavelength of the emitted electromagnetic radiation depends on the size and material of the grating comprising the slit array (e.g. the nano slit array (NSA)). Specifically, the metal used for the slit array, the width of the blocks, the height of the blocks, the width of the slit and the periodicity of the blocks. In one embodiment, the wavelength of the emitted electromagnetic radiation depends on the structure and material of the dielectric material (dielectric layer(s)). In one embodiment, the wavelength of the emitted electromagnetic radiation depends on the number of the dielectric layers, the thickness of the dielectric layers, on the physical/chemical interaction between adjacent layers or a combination thereof.

In one embodiment, the emitted EM radiation is measured and/or collected by a detector. In one embodiment, the detector is a spectrometer. In one embodiment, the optical device is cooled.

In one embodiment, device and methods of this invention enhance the electromagnetic (EM) field within the layered non-linear material. In one embodiment, enhanced EM field means that at a certain locations in the device (i.e within the layered non-linear material) the EM field is of much higher intensity than the field irradiating the device.

In one embodiment, this invention provides a method of IR light sensing, said method comprising:

a. providing an optical device comprising:

a grating of a slit array and one or more dielectric layers, wherein said layers comprise non linear material and said layers are positioned on top of said grating, below said grating or on top and below said grating and wherein said layer(s) has no significant linear absorption at a certain IR wavelength range of the electromagnetic radiation spectrum;

b. providing an optical detector sensitive to visible light;

c. using said detector for collecting and/or measuring visible electromagnetic radiation emitted from said optical device.

In one embodiment, this invention provides a method of IR imaging, said method comprising:

a. providing an array of optical devices, wherein each optical device comprising:

a grating of a slit array and one or more dielectric layers, wherein said layers comprise non linear material and said layers are positioned on top of said grating, below said grating or on top and below said grating and wherein said layer(s) has no significant linear absorption at a certain IR wavelength range of the electromagnetic radiation spectrum;

b. providing optical detectors sensitive to visible light such that each detector addresses one of said optical devices;

c. using said detectors for collecting and/or measuring electromagnetic radiation emitted from each of said optical devices; and

d. compiling an image from said electromagnetic radiation emitted from each of said optical devices.

In one embodiment, the methods of this invention for IR sensing and IR imaging comprise the use of a detector for collecting and/or measuring the emitted radiation. In one embodiment, the detector is in contact with the gratings or with the optically non linear material. In one embodiment, the optical detector can be the substrate or the nonlinear material itself. In one embodiment, the detector is in contact with the gratings or with the optically non linear material.

In one embodiment, the IR radiation is generated by a laser. In one embodiment, the IR radiation is generated by a light emitting diode (LED). In one embodiment, the IR radiation is generated by an object. In one embodiment, the IR radiation is generated by a vehicle. In one embodiment, the IR radiation is generated by a person or an animal. In one embodiment, the IR radiation is generated by any IR source as known to a person of ordinary skill in the art.

In one embodiment, IR imaging refers to an image constructed from received EM radiation in the IR range. In one embodiment, IR imaging is done by dividing a receiving panel to regions such that each region receives radiation form a different region of the object to be imaged. In one embodiment, IR imaging device is synonym with a camera. In one embodiment, an IR imaging system is capable of forming a picture of an object that irradiates EM radiation in the IR range. In one embodiment, IR imaging systems of the invention, absorbs EM radiation in the IR range and transmits radiation in higher frequencies. In one embodiment, IR imaging systems comprise optical devices that absorb IR radiation, detectors for EM radiation transmitted by the device and computing systems to convert the transmitted frequencies from all regions of the device(s) to an image. In one embodiment, the IR imaging systems further comprise an IR radiation source. In one embodiment, systems of the invention comprise cameras.

In one embodiment, the number of optical devices arranged in an array for the purpose of IR imaging ranges between 1 and 10,000,000.

In one embodiment, the image is obtained using a computer. In one embodiment, the detector is in contact with said gratings or with said optically non linear material. In one embodiment, the IR radiation is generated by a laser. In one embodiment, the IR radiation is generated by an object. In one embodiment, the IR radiation is generated by a person or an animal.

In one embodiment, the device of this invention and methods of use thereof are directed to amplification of the electromagnetic field and thereby amplification of the non-linear signal. In another embodiment the amplification is controlled by the polarity of the radiation. In another embodiment the amplification is controlled by the angle by which the electromagnetic beam is irradiated. In another embodiment the amplification is controlled by the intensity of the irradiated electromagnetic beam. In another embodiment the amplification is controlled by the wavelength of the irradiated beam. In another embodiment the amplification is controlled by the thickness of the dielectric layers. The amplification of the non-linear signal is positioned/located within the layers of the dielectric material (i.e within the layers of the non-linear material). The amplification of the non-linear signal is not located within the slits of the slit array. In one embodiment, only a small portion of the non-linear signal is generated at the slits (a portion that is less than 1% or less than 5% or less than 10% of the total non linear signal) while most of the signal (more than 99%, more than 90% or more than 95%) is generated within the at least one layer of the dielectric material in the device.

In one embodiment, the device of this invention and methods of use thereof are directed to amplification of the electromagnetic field and thereby amplification of the non-linear signal. In another embodiment the field enhancements is designed to be in the dielectric layer/layers on top or below the grating. Such design provides much higher enhancement than a grating wherein an homogeneous dielectric material is embedded within the slits only (where the field enhancements are inside the slits), because in the first case a much higher optical Q-factor can be achieved using the confinement of the electromagnetic field inside the dielectric layers which have much less optical loss than a metal. The electromagnetic field inside the slits, in contrary, would suffer from large metal absorption losses.

In one embodiment, system and methods of this invention allow strong amplification of intensity for a broad optical frequency range. Systems and methods of this invention allow amplification of light intensity for large spectral ranges. In one embodiment, devices of the invention comprise Near IR to visible optical up-converter. In one embodiment, devices of the invention comprise Near IR to visible optical up-converter and detector. In one embodiment, devices of the invention comprise IR and/or Near IR electro-optical detector.

In one embodiment, devices and methods of the invention provide efficient Near-IR light detection. Efficient light detection is essential for many applications including: telecom and information, military and civilian NIR sensing and imaging.

In one embodiment, devices and methods of this invention allow to efficiently convert NIR light to visible light utilizing the optical nonlinearities of materials. In particular, using a two photon absorption process (TPA) that occurs within certain materials.

In conventional devices, nonlinear response is weak, but depends on incoming light intensity. Devices of this invention utilize Bragg metallic grating for enhancing the light intensity in the device. In one embodiment, this results in efficient TPA processes. The efficient TPA process allows direct electrical detection or light up-conversion and detection of the incoming radiation. In one embodiment, the TPA process is illustrated in FIG. 1 (c). In one embodiment, two photons (two up arrows on the left) of low energy are being absorbed by a non-linear material. Following the TPA, a non-radiative process occurs (illustrated by a small, straight, diagonally right-pointing arrow). A photon is then emitted such that the emitted photon possesses higher energy than the energy of each of the incoming photons (down arrow in FIG. 1(c)). In electro-optical devices of the invention, the TPA is followed by an electron-hole generation. The energy supplied by the absorption of the two photons is sufficient to generate the electron hole pair whereas the energy provided by just one photon is not sufficient to generate such e-h pair.

In one embodiment, enhancement of a waveguide wherein the dielectric layers comprise either polymer filled with quantum dots or bulk GaAs in a high intensity mode results in an intensity enhancement of up to ˜23,000 and an average enhancement of ˜8000. In one embodiment, devices and methods of the invention provide a detectable upconverted visible photon flux for low incoming IR intensities. In one embodiment, the upconverted light can be to made to emit to a given direction. In one embodiment, incoming IR light intensity (at 1.55 microns) is upconverted to photon flux (at ˜840 nm) that is emitted from the device. In one embodiment, microns refer to micrometers.

In one embodiment, this invention provides an electro-optical device comprising a grating of a slit array, and a PN junction, a PIN junction or an avalanche photo diode (APD), wherein the PN junction, the PIN junction or the avalanche photo diode is positioned on top of the grating, below the grating or on top and below the grating and wherein the PN junction, the PIN junction or the avalanche photo diode has no significant linear absorption at a certain wavelength range of the electromagnetic radiation spectrum, and wherein the PN junction, the PIN junction or the avalanche photo diode generates electron-hole pairs upon non-linear absorption of electromagnetic radiation at the wavelength range and wherein an electrical current is generated by the electron-hole pairs.

In one embodiment, the device further comprises a current meter connected to the PN junction, the PIN junction or to the avalanche photo diode. In one embodiment, the device further comprise a power supply connected to the PN junction, the PIN junction or to the avalanche photo diode. In one embodiment, the PN junction, the PIN junction or the avalanche photo diode comprise GaAs, AlGaAs, Si, silicon dioxide, Quartz, Ge, GaN, GaAlN, InGaAs, InGaP or a combination thereof.

In one embodiment, a portion of the PN junction, the PIN junction or the avalanche photo diode is further positioned within the slits of the grating.

In one embodiment, the grating in electro-optical devices and methods of this invention comprises an array of blocks separated by slits as discussed herein above for the optical devices. In one embodiment, the dimensions (width, height, spacings) of the blocks, slits and periods of grating of the electro-optical devices are as discussed herein above for the optical devices.

In one embodiment, the certain wavelength range is within the IR range. In one embodiment, the non linear absorption is two-photon absorption.

In one embodiment, the electron-hole pair is generated by absorption of energy at the near IR and/or at the visible electromagnetic range.

In one embodiment, this invention provides a method of detection of electromagnetic radiation, the method comprising:

a. providing an electro-optical device comprising:

a grating comprising a slit array and a PN junction, a PIN junction or an avalanche photo diode, wherein the PN junction, the PIN junction or the avalanche photo diode is positioned on top of the grating, below the grating or on top and below the grating and wherein the PN junction, the PIN junction or the avalanche photo diode has no significant linear absorption at a certain wavelength range of the electromagnetic radiation spectrum;

b. connecting the PN junction, the PIN junction or the avalanche photo diode to a current meter;

c. irradiating the electro-optical device with electromagnetic radiation at the certain wavelength range such that the PN junction, the PIN junction or the avalanche photo diode generates electron-hole pairs upon non-linear absorption of the electromagnetic radiation at the wavelength range and wherein an electrical current is generated by the electron-hole pairs; and

d. using the current meter for detecting and/or measuring the current;

wherein upon the irradiation of the electro-optical device, the electromagnetic intensity within the PN junction, the PIN junction or the avalanche photo diode is enhanced resulting in amplification of a two-photon absorption process followed by amplified current generation by the PN junction, the PIN junction or the avalanche photo diode.

In one embodiment, the PN junction, a PIN junction or an avalanche photo diode is connected to a power supply. In one embodiment, the power supply is used to apply voltage to the PN junction, a PIN junction or an avalanche photo diode.

In one embodiment, the PN junction, the PIN junction or the avalanche photo diode comprise GaAs, AlGaAs, Si, silicon dioxide, Quartz, Ge, GaN, GaAlN, InGaAs, InGaP or a combination thereof.

In one embodiment, the electron-hole pair is generated by absorption of electromagnetic radiation in the IR range, in the near IR range, in the visible range or a combination thereof.

In one embodiment, the irradiated electromagnetic radiation is broad-band. In one embodiment, the irradiated radiation is polarized. In one embodiment, the intensity of the absorbed radiation ranges between 10 and 100 times the intensity of the irradiated electromagnetic radiation.

In one embodiment, this invention provides a method of IR light sensing, the method comprising:

a. providing an electro-optical device comprising:

a grating comprising a slit array and a PN junction, a PIN junction or an avalanche photo diode, wherein the PN junction, the PIN junction or the avalanche photo diode is positioned on top of the grating, below the grating or on top and below the grating and wherein the PN junction, the PIN junction or the avalanche photo diode has no significant linear absorption at a certain wavelength range of the electromagnetic radiation spectrum, and wherein the PN junction, the PIN junction or the avalanche photo diode generates electron-hole pairs upon non-linear absorption of electromagnetic radiation at the wavelength range and wherein an electrical current is generated by the electron-hole pairs;

b. connecting the dielectric material to a current meter;

c. using the current meter for detecting and/or measuring current generated by the electro-optical device;

wherein upon IR sensing by the electro-optical device, the IR electromagnetic intensity within the PN junction, a PIN junction or an avalanche photo diode is enhanced resulting in amplification of IR two-photon absorption process within the PN junction, a PIN junction or an avalanche photo diode followed by amplified current generation by the PN junction, a PIN junction or an avalanche photo diode.

In one embodiment, the PN junction, a PIN junction or an avalanche photo diode is connected to a power supply. In one embodiment, the power supply is used to apply voltage to the PN junction, a PIN junction or an avalanche photo diode. In one embodiment, the IR light is generated by a laser, by a light emitting diode or by an object.

In one embodiment, this invention provides a method of IR imaging, the method comprising:

a. providing an array of electro-optical devices, wherein each electro-optical device comprising:

a grating comprising a slit array and a PN junction, a PIN junction or an avalanche photo diode, wherein the PN junction, the PIN junction or the avalanche photo diode is positioned on top of the grating, below the grating or on top and below the grating and wherein the PN junction, the PIN junction or the avalanche photo diode has no significant linear absorption at a certain wavelength range of the electromagnetic radiation spectrum, and wherein the PN junction, the PIN junction or the avalanche photo diode generates electron-hole pairs upon non-linear absorption of electromagnetic radiation at the wavelength range and wherein an electrical to current is generated by the electron-hole pairs;

b. providing electrical current detectors such that each detector addresses one of the electro-optical devices;

c. using the current detectors for collecting and/or measuring current generated by each of the electro-optical devices; and

d. compiling an image from the current generated by each of the electro-optical devices.

In one embodiment, the PN junction, the PIN junction or the avalanche photo diode is connected to a power supply. In one embodiment, the power supply is used to apply voltage to the PN junction, the PIN junction or the avalanche photo diode. In one embodiment, the image is obtained using a computer.

In one embodiment, the term nanoslit array (NSA) refers to the grating of the device without the dielectric layers. In another embodiment, the term nanoslit array, in practice, refers to the device which comprises both the slit array and the dielectric layers.

In one embodiment, this invention provides NIR detectors that are based on large bandgap materials. In one embodiment, devices and methods of the invention comprise detectors that do not need active cooling. In one embodiment, electro-optical devices of the invention are not bulky. In one embodiment, electro-optical devices of the invention are not expensive. In one embodiment, electro-optical devices of the invention enable detection of NIR light using conventional cheap detectors which are sensitive to visible light. Detectors of the invention comprise for example Si-based photodiodes and CCD's.

In one embodiment, devices and methods of the invention provide cheap and efficient narrow band detectors for specific laser wavelength. Such detectors are applicable for example for laser imaging technologies and tagging.

In one embodiment, a pn or a PN junction is a term that describes the region of contact of a p-type semiconductor and an n-type semiconductor. Most diodes consist of a pn junction. In one embodiment, a photodiode comprises a pn junction. In one embodiment, pn junctions comprise a p-doped Si layer that is brought into contact with an n-doped Si layer. In one embodiment, the pn junction comprises GaAs. In one embodiment, A PN junction is a device formed by combining p-type semiconductor (doped with e.g. B, Al) and n-type semiconductor (doped with e.g. P, As, Sb) wherein the two (p and n) semiconductor materials are held together in close contact. A PIN junction is a diode with a wide, lightly doped intrinsic semiconductor region between a p-type semiconductor and an n-type semiconductor region. The p-type and n-type regions are typically heavily doped. The wide intrinsic region in a PIN is in contrast to an ordinary PN diode. The pin diode consists of heavily doped p and n regions separated by an intrinsic region. Avalanche photodiode (APD) is a high sensitivity photodiode that operates at high speeds and high gain by applying a reverse bias. APD's Deliver a higher S/N than PIN photodiodes and is widely used in optical rangefinders, spatial light transmission, scintillation detectors, etc.

In one embodiment, devices of this invention comprise active Si PN or PIN based visible detector. In one embodiment, enhanced nonlinear TPA inside the active Si PN or PIN based visible detector, results in e-h (electron-hole) pairs and a current. In one embodiment, the TPA process allows detection of light wavelength that corresponds to energy smaller than the band gap of the detector. In one embodiment, the device is irradiated with light of a wavelength that corresponds to an energy that is smaller than the energy required to produce an electron-hole pair in the electro-optical device. This incoming light undergoes enhancement within the device and enhanced TPA occurs within the device. The TPA generates energy that is at the band gap or is higher than the band gap of the dielectric material and therefore allows the generation of electron-hole pairs. The e-h pairs generate detectable current in one embodiment. The slit array enables the enhancement of the TPA process within the device, thus allowing a stronger electrical signal, above the detectable level.

In one embodiment, devices of the invention comprise detectors. In one embodiment the detectors are electro-optical detectors. In one embodiment, detectors of the invention are sensitive for low light intensities. In one embodiment, detectors of the invention are applicable for detection of light of a wavelength of around 2.1 microns. In one embodiment, detectors of the invention are applicable for detection of light of a wavelength of around 1.06 micron or of around 1.55 micron. In one embodiment, detectors of the invention are applicable for detection of light of a wavelength ranging between 1.0 microns and 2.0 microns. In one embodiment, detectors of the invention are applicable for detection of light of a wavelength ranging between 0.8 microns and 3.0 microns. In one embodiment, light detection by detectors of this invention is enabled by the generation of current as a result of enhanced TPA within the PN, PIN or avalanche diode of the invention, wherein the enhancement of the TPA is enabled by the slit array. In one embodiment, the slit array is in contact with the PN, PIN or with the avalanche diode. In one embodiment, detectors and devices of the invention are or comprise photodiodes.

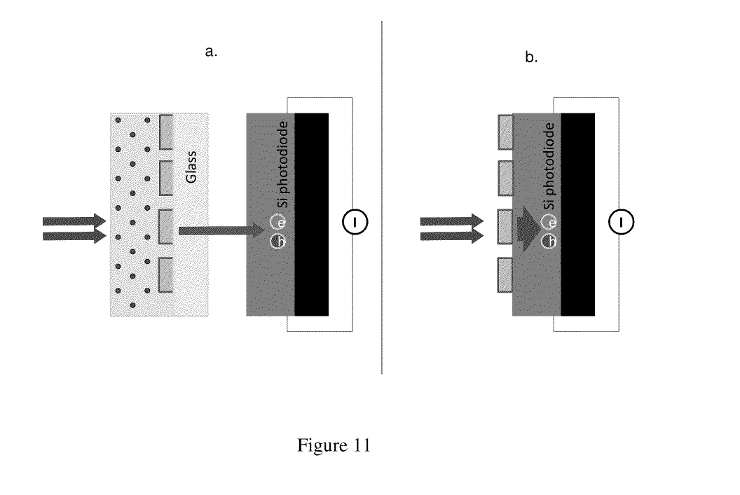

In one embodiment, this invention provides a GaAs/Si-based NIR detector comprising a slit array and a PN, PIN or am avalanche photodiode (FIG. 11b). In one embodiment, this invention provides a semiconductor nanocrystal-based light up-converter (FIG. 11a). The nanocrystal-based light upconverter may be assembled with a semiconductor detector to detect the up converted light (FIG. 11a).

In one embodiment, devices and methods of the invention are applicable to Near IR light detection, to Near IR light imaging, to spectrally selective detection, to polarization selective detection, and to light concentrators for solar cells. In one embodiment, devices and methods of the invention are applicable to both military and civilian (e.g. telecom) light detection in the 0.8-2.2 μm spectral range. In one embodiment, devices and methods of this invention are directed toward low cost, non-cooled, NIR detection and imaging technologies.

In one embodiment, devices and methods of the invention are directed to applications including IR cameras. Such applications include but are not limited to thermography (e.g. predictive maintenance, building inspection and others), for commercial vision (e.g. surveillance/CCTV, automotive, fire fighting, maritime and others) and for military (e.g. thermal weapon sight, vehicle vision, soldier portable vision, weapon station and others).

In one embodiment, devices and methods of the invention comprise IR sensors. In one embodiment, IR sensors of the invention allow high efficiency of the detector in the wavelength range of operation. In one embodiment, IR sensors of the invention increase the efficiency of the TPA process by 10⁴ (10,000) or by a similar range, enhancing the detectivity to a practical range. In one embodiment, IR sensors of the invention combine low noise Si sensor to narrow bandpath IR convertor, filtering most of the background thermal noise. In one embodiment, IR sensors of the invention based on the TPA phenomena do not add to the existing image sensor response time. In one embodiment, IR sensors of the invention are of low complexity, low maintenance, low failure rate and of low energy consumption. In one embodiment, the passive layers in IR sensors of the invention do not add complexity, failure or energy consumption to the device. In one embodiment, IR sensors of the invention and cameras of the invention are low cost devices. In one embodiment, low cost devices of the invention are installed in low cost systems.

In one embodiment, devices of the invention comprise dielectric layers. In one to embodiment, the dielectric layer(s) has/have no significant linear absorption at a certain wavelength range of the electromagnetic radiation spectrum. In one embodiment, ‘no significant linear absorption’ means very little absorption, absorption below a detectable limit, negligible absorption for a certain application or a combination thereof. In one embodiment, ‘no significant absorption means less than 0.01%, less than 0.1% absorption, less than 1% absorption, less than 5% absorption, less than 10% absorption. In one embodiment, no significant absorption means transparent. In one embodiment, no significant absorption means no absorption.

In one embodiment, an electro-optical device also refers to an opto-electric device. In one embodiment, electro-optical devices of the invention are devices that generate an electrical signal upon receipt of an optical signal.

In one embodiment, the term “a” or “one” or “an” refers to at least one. In one embodiment the phrases “two or more” or “at least two” may be of any denomination, which will suit a particular purpose. In one embodiment, “about” or “approximately” or “roughly” may comprise a deviance from the indicated term of +1%, or in some embodiments, −1%, or in some embodiments, ±2.5%, or in some embodiments, ±5%, or in some embodiments, ±7.5%, or in some embodiments, ±10%, or in some embodiments, ±15%, or in some embodiments, ±20%, or in some embodiments, ±25%.

The following examples are presented in order to more fully illustrate the preferred embodiments of the invention. They should in no way be construed, however, as limiting the broad scope of the invention.

### EXAMPLES

### Example 1

### Broad-Band Amplification of Two Photon Absorption

To demonstrate the enhancement of a TPA (two photon absorption) process in NQD's using resonant local field enhancements in metallic NSA's, metallic NSA structures covered by a NQD-in-polymer matrix (PFCB) were fabricated. The NSA resonances were designed to occur at wavelengths which are at half the wave-length of the higher excitonic transitions of the NQDs (see FIG. 1c). By exciting the structure with laser pulses at these resonant wavelengths (˜1500 nm), the strong local field enhancements of the structure enhanced to the TPA process in the NQD's, leading to a population of the NQD excited states. These excited states then decay radiatively from the first excitonic transition wavelength (˜950 nm), leading to light upconversion from the structure. This procedure is schematically illustrated in FIG. 1c.

The samples consisted of NIR emitting NQD's in a transparent polymer, embedded in an Aluminum based NSA, as is schematically shown in FIG. 1a. The NQD's investigated were InAs/CdSe core/shell type I, dispersed in a polymer matrix of perfluorocyclobutane (PFCB). A typical emission spectrum of the NQD's is shown in FIG. 1b, peaking around ˜950 nm, corresponding to the emission wavelength of the first excitonic transition, inhomogeneously broadened by the small size distribution of the NQD's. The polymer has a refractive index of n˜1.51. The NQD/polymer mixture was spin-coated on the NSA forming a H˜1.8 μm thick layer (FIG. 1a).

The NSA consisted of an Aluminum grating on a glass substrate, as depicted in FIG. 1a with a height of h=0.25 μm. Two different grating periods and slit widths were used, depending on the incoming excitation polarization with respect to the grating (either TE or TM polarizations). For the experiments with an excitation having TM (TE) polarization, the grating had a period of d=0.8 μm (d=1 μm) and a slit width of a=0.35 μm (a=0.45 μm) respectively. These parameters where chosen so that the structure resonances (in both TE and TM) would match the excitation wavelengths required for the TPA process as described above.

The excitation was done using a tunable Optical Parametric Oscillator (OPO) pumped by a mode-locked 80 MHz Ti:Sapphire laser, producing sub-100 fs pulses in the near infra-red (NIR) spectral range (1400 nm-1600 nm). The pulse was either TM or TE polarized with respect to the NSA structure. The pulse was slightly focused on the sample, and the resulting upconverted fluorescence was collected and analyzed by a spectrometer with a Pixis CCD camera (FIG. 1a). This fluorescence intensity was normalized to the fluorescence intensity from an identical reference sample but without the NSA.

### Results

In order to analyze the experimental results, the total absorption cross-section of the NQDs was firstly defined as:

σ(λ,1)=σ₀(λ)|σ⁽²⁾(λ)I Equation 1:

where σ₀(λ) is due to the linear resonant absorption of the NQD optical transitions, and σ⁽²⁾(λ) is the cross-section of the TPA of the incoming light at half the NQD excitonic optical transition (with intensity I). As under such excitation conditions σ₀ vanishes, the total cross-section depends linearly on the excitation intensity. The upconverted fluorescence intensity I_{uc} is proportional to the number of NQDs excited by TPA, defined as N_{NQD}=σI/hω yielding:

Equation 2:

$${I}_{U C} ∝ {N}_{NQD} = \frac{{σ}^{( 2 )} {/}^{2}}{ℏω}$$

This equation shows that I_{UC} I². The enhancement factor of the incoming light inside the NSA structure is defined for various excitation wavelengths λ as γ(λ). Therefore, the intensity inside the structure is enhanced as I→γI. As a result, the measured upconverted fluorescence I_{UC} from the NSA structure, normalized to the fluorescence from the reference without the NSA, is equal to γ².

From equation (2), a quadratic behavior of I_{UC} is expected as the peak power of the excitation laser is increased. This is experimentally confirmed in FIG. 6 where the total fluorescence of the NQD's in a reference sample exhibits such quadratic behavior.

FIG. 6a shows an example of an enhancement of Iuc in NSA structures (in TM polarization). It is clear that the induced fluorescence is enhanced due to the enhanced TPA. The square of the experimental enhancement intensity factor (γ²ₑₓₚ) is extracted by integrating the full spectra to get the total induced fluorescence and normalizing it to the emission from the reference sample. In addition, it was verified that γ is power independent as expected, which is presented in FIG. 6b.

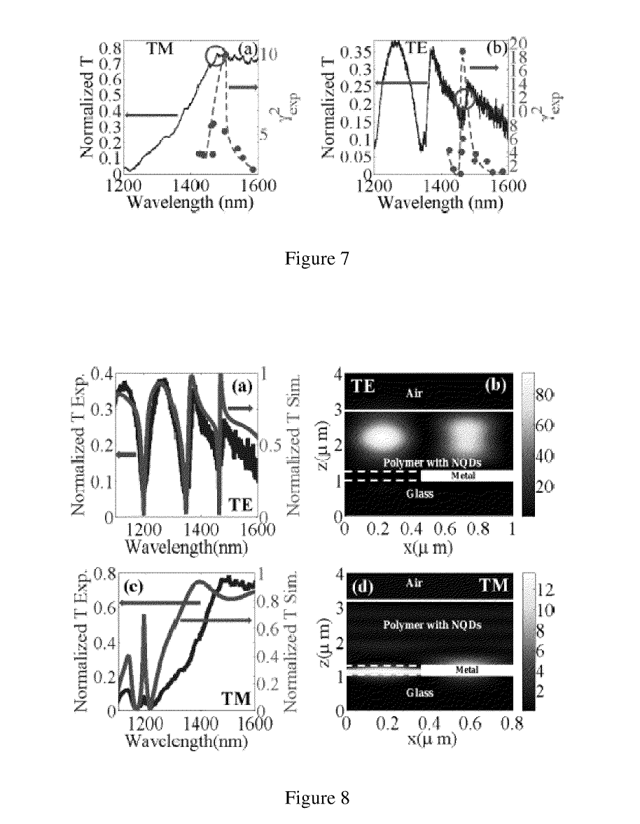

Next, the dependence of γ²ₑₓₚ on the excitation wavelength was measured. This dependence is presented by the green dots in FIG. 7a for the TM excitation and in FIG. 7b for TE excitation. It is evident that in both TE and TM, the nonlinear enhancement is strongly wavelength dependent and exhibits a resonant behavior. In order to understand the nature of this resonant behavior, the transmission spectra of the NSA structure in both polarizations was measured. The corresponding transmission measurements in TM and TE are presented by the blue lines in FIGS. 7a and b respectively. Both transmission spectra show clear EOT resonances. These peaks in transmission are the result of the standing EM resonances of the confined Bragg modes of the structure These Fabri-Perot like confined resonances are accompanied by a strong enhancement of the EM intensity inside the structure. This is verified by a numerical calculation of the optical response of our structures, based on a dynamical diffraction formalism. FIG. 8a,c presents a comparison of the measured transmission spectra to the calculated one for both TE and TM respectively. A good agreement is found between the calculation and the measurement, and the various peaks are identified as various orders of the standing wave resonances (the differences in the absolute magnitude of the transmission between the calculation and the experiment are probably due to the inhomegenity of the grating). In particular, the EM intensity distributions in the structure around the first EOT (Extraordinary transmission (or enhanced transmission) resonance for both polarizations was calculated. The circles in FIG. 7 point to the spectral position of the maximal calculated field enhancement for the TE and TM polarizations. It can be seen from FIG. 7 that there is a good correspondence between the spectral location of the peak in γ² and the maximal field enhancement in both polarization. This is a strong indication that the mechanism behind the TPA enhancement is the local field enhancements at the EOT resonances. The calculated spatial distribution of the field intensities at those EOT resonances are plotted in FIG. 8b, 8d for TE and TM respectively, normalized to the EM field intensities without the NSA structure. It can be seen that indeed strong local field enhancements are obtained in our structures, reaching a maximal value of ˜90 for TE and ˜13 for TM.

To compare the theoretical calculations to the experimental results, the expected nonlinear enhancement factor had to first be obtained from the near field calculations. For that, it was assumed that the NQD are evenly dispersed in the polymer layer on the metallic grating. With this assumption, the spatially averaged value of the TPA enhancement factor (γ_{calc}) should be given by:

Equation 3:

$${γ}_{calc} ( λ ) = \frac{1}{{ɛ}_{PFCB}} \frac{{\int }_{unit - cell} I ( r , λ ) d \overline{r}}{{\int }_{unit - cell} d \overline{r}}$$

where I(r, λ) is the calculated field intensity enhancement in each point in the polymer layer in a unit cell of the NSA structure and ∈_{PFCB} is the dielectric constant of the polymer.

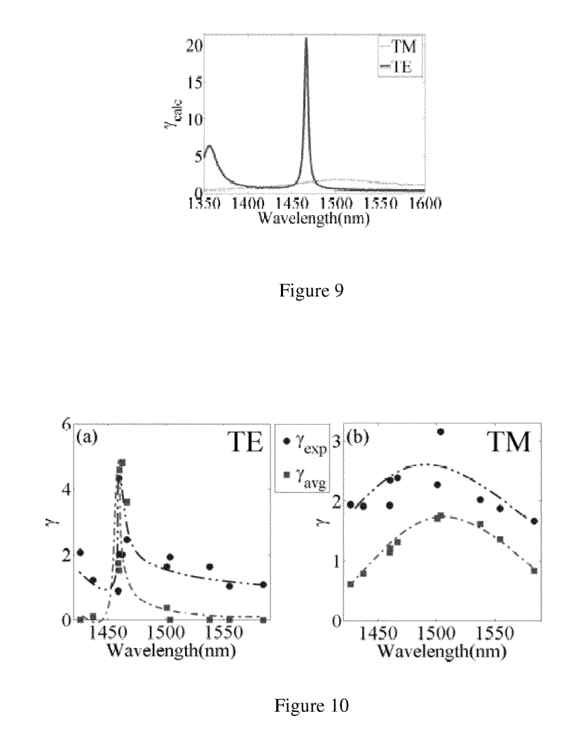

FIG. 9 shows the dependence of γcalc on the excitation wavelength. The largest enhancement for TE is at 1466 nm with a maximal value of ˜21 and a typical width of 3 nm. For to the TM polarization the enhancement is broader, peaking at 1505 nm. The reason for this difference in the maximal value of γ_{calc} between the two polarizations can be explained as follows: the field enhancements are larger for the TE polarization than for the TM polarization due to a better mode confinement. Also, while in TM the maximal enhancement is restricted only to the slit volume, the volume of the high field enhancements in TE polarization is larger and resides mostly in the thicker polymer layer. This leads to a better overlap of the enhanced EM fields with the NQDs. Next, the finite spectral width of the laser pulse (˜20 nm), which excites the inhomogeneously broadened spectrum of the NQDs inside the resonant structure was taken into account. This means that different NQDs having a TPA resonance at different wavelengths covered by the laser pulse spectrum experience different laser powers as well as different local field enhancements. To take this effect into account the expected averaged TPA enhancement was calculated by:

Equation 4:

$${γ}_{avg} = \frac{\int {γ}_{calc} ( λ ) P ( λ ) d λ}{\int P ( λ ) d λ} ,$$

where P(λ) is the excitation laser pulse spectrum and γ_{calc}(λ) is taken from Equation 3.

FIG. 10a, 10b shows a comparison of the experimentally measured enhancement factor, γₑₓₚ to the calculated one, γavg, for TE and TM polarizations respectively. A very good agreement between the calculated values and the experimental values is obtained, confirming both the interpretation of the origin of the observed enhancement as well as validating the numerically calculated field intensities and the NQDs TPA enhancements in the NSA structure.

In summary, the enhancement of two-photon absorption processes in nanocrystal quantum dots and of light upconversion from the IR to the NIR spectral regime has been shown using a hybrid optical device in which NIR emitting InAs quantum dots were embedded on top a metallic nanoslit array. Our measurements and calculations show that the underlying mechanism behind the resonant enhancement of this nonlinear optical process is the strong local field enhancements inside the NSA structure which in turn result from the standing EM waves at the EOT resonances. A maximal TPA enhancement of more than 20 was inferred. Using the numerical model developed, “hot spots” in the structure where maximal field enhancement is achieved were identified: in TE polarization, the maximal field of the first EOT resonance occurs mainly at the dielectric waveguide layer on top of the metal grating, while for the first EOT resonance in TM, the maximal field occurs mostly inside the slit and very close to the metal-dielectric interface. This can be used as a guide for designing and optimizing efficient nonlinear devices based on such NSA structures. For example, one can fill the slits and the top dielectric layer with different nonlinear media (such as two different types of NQDs), and control which one will be activated using different polarizations. The maximal enhancement can be much improved by a better design, e.g., using less lossy metal in the IR spectral regime, and optimizing the metal thickness and the slit width. It can be concluded that subwavelength metallic nanostructures may be used for a range of possible nonlinear optical devices based on nanocrystal quantum dots.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. An optical device comprising a grating, said grating comprising a slit array, and one or more dielectric layers, wherein at least one of said layers comprise non linear material and said layers are positioned on top of said grating, below said grating or on top and below said grating and wherein said layer(s) has no significant linear absorption at a certain wavelength range of the electromagnetic radiation spectrum.

2. The device of claim 1, wherein said dielectric layers comprise GaAs, AlGaAs, Si, silicon dioxide, Quartz, Ge, GaN, GaAlN, InGaAs, InGaP or a combination thereof.

3. The device of claim 1, wherein said non linear material comprise a polymer embedded with quantum dots, wherein said quantum dots is comprising InAs, CdSe, PbS, PbSe, CdTe, Ge, Si, GaAs, InGaAs or a combination thereof.

4. The device of claim 1, wherein said non linear material is further positioned within said slits of said grating.

5. The device of claim 1, wherein said dielectric layers are positioned on top of said grating and said grating is positioned on a substrate.

6. The device of claim 5, wherein said substrate comprises glass.

7. The device of claim 1, wherein said grating comprises an array of blocks separated by slits.

8. The device of claim 7, wherein the width of said blocks ranges between 400 nm and 600 nm.

9. The device of claim 7, wherein the height of said blocks ranges between 10 nm and 1500 nm.

10. The device of claim 1, wherein the width of said slits ranges between 100 nm and 750 nm.

11. A method of amplification of an electromagnetic intensity within layered non-linear material resulting in amplification of non-linear signals, said method comprising:
a. providing an optical device comprising:
a grating comprising a slit array, and one or more dielectric layers, wherein at least one of said layers comprise non linear material and said layers are positioned on top of said grating, below said grating or on top and below said grating and wherein said layer(s) has no significant linear absorption at a certain wavelength range of the electromagnetic radiation spectrum;
b. irradiating said optical device with an electromagnetic radiation at said wavelength range or portions thereof; and
c. collecting and/or measuring electromagnetic radiation emitted from said optical device, wherein said radiation comprising a non linear signal;
wherein upon said irradiation of said optical device, the electromagnetic intensity within said layered optically non-linear material is enhanced resulting in amplification of said non-linear signal.

12. The method of claim 11, wherein said dielectric layers comprise GaAs, AlGaAs, Si, silicon dioxide, Quartz, Ge, GaN, GaAlN, InGaAs, InGaP or a combination thereof.

13. The method of claim 11, wherein said non linear material is comprising a PFCB polymer embedded with quantum dots, wherein said quantum dots comprising InAs, CdSe, PbS, PbSe, CdTe, Ge, Si, GaAs, InGaAs or a combination thereof.

14. The method of claim 11, wherein said non linear material is further positioned within said slits of said grating.

15. The method of claim 11, wherein said dielectric layers are positioned on top of said grating and said grating is positioned on a substrate.

16. The device of claim 15, wherein said substrate comprises glass.

17. The method of claim 11, wherein said non-linear signal is the result of a two-photon absorption (TPA) process.

18. The method of claim 11, wherein said non-linear signal is a result of a second harmonic generation (SHG) process.

19. The method of claim 11, wherein said irradiated electromagnetic radiation is in the IR range.

20. The method of claim 11, wherein said irradiated electromagnetic radiation is broad-band.

21. The method of claim 20, wherein said broad-band ranges between 1000 nm and 2000 nm.

22. The method of claim 11, wherein said emitted electromagnetic radiation is in the near IR range, in the visible range or a combination thereof.

23. The method of claim 11, wherein the majority of said emitted electromagnetic radiation is at a specific wavelength.

24. The method of claim 11, wherein said irradiated electromagnetic radiation, said emitted electromagnetic radiation or a combination thereof is polarized.

25. The method of claim 11, wherein the intensity within said device ranges between 10 and 100 times said irradiated electromagnetic intensity.

26. A method of IR light sensing, said method comprising:
a. providing an optical device comprising:
a grating of a slit array and one or more dielectric layers, wherein said layers comprise non linear material and said layers are positioned on top of said grating, below said grating or on top and below said grating and wherein said layer(s) has no significant linear absorption at a certain IR wavelength range of the electromagnetic radiation spectrum;
b. providing an optical detector sensitive to visible light;
c. using said detector for collecting and/or measuring visible electromagnetic radiation emitted from said optical device.

27. The method of claim 26, wherein said radiation emitted from said optical device is the result of an IR two photon absorption process occurring within said dielectric layers followed by visible fluorescence.

28. The method of claim 26, wherein said radiation emitted from said optical device is the result of a second harmonic generation of a photon in the visible from two IR photons.

29. The method of claim 26, wherein said detector is in contact with said gratings or with said optically non linear material.

30. The method of claim 26, wherein said IR light is generated by a laser, by a light emitting diode, by an object or a combination thereof.

31. A method of IR imaging, said method comprising:
a. providing an array of optical devices, wherein each optical device comprising:
a grating of a slit array and one or more dielectric layers, wherein said layers comprise non linear material and said layers are positioned on top of said grating, below said grating or on top and below said grating and wherein said layer(s) has no significant linear absorption at a certain IR wavelength range of the electromagnetic radiation spectrum;
b. providing optical detectors sensitive to visible light such that each detector addresses one of said optical devices;
c. using said detectors for collecting and/or measuring electromagnetic radiation emitted from each of said optical devices; and
d. compiling an image from said electromagnetic radiation emitted from each of said optical devices.

32. The method of claim 31, wherein said image is obtained using a computer.

33. An electro-optical device comprising a grating of a slit array and a PN junction, a PIN junction or an avalanche photo diode, wherein said PN junction, said PIN junction or said avalanche photo diode is positioned on top of said grating, below said grating or on top and below said grating and wherein said PN junction, said PIN junction or said avalanche photo diode has no significant linear absorption at a certain wavelength range of the electromagnetic radiation spectrum, and wherein said PN junction, said PIN junction or said avalanche photo diode generates electron-hole pairs upon non-linear absorption of electromagnetic radiation at said wavelength range and wherein an electrical current is generated by said electron-hole pairs.

34. The device of claim 33, wherein said device further comprises a current meter connected to said PN junction, said PIN junction or to said avalanche photo diode.

35. The device of claim 33, wherein said device further comprise a power supply connected to said PN junction, said PIN junction or to said avalanche photo diode.

36. The device of claim 33, wherein said PN junction, said PIN junction or said avalanche photo diode comprise GaAs, AlGaAs, Si, silicon dioxide, Quartz, Ge, GaN, GaAlN, InGaAs, InGaP or a combination thereof.

37. The device of claim 33, wherein a portion of said PN junction, said PIN junction or said avalanche photo diode is further positioned within said slits of said grating.

38. The device of claim 33, wherein said grating comprises an array of blocks separated by slits.

39. The device of claim 38, wherein the width of said blocks ranges between 400 nm and 600 nm.

40. The device of claim 38, wherein the height of said blocks ranges between 10 nm and 1500 nm.

41. The device of claim 38, wherein the width of said slits ranges between 100 nm and 750 nm.

42. The device of claim 33, wherein said certain wavelength range is within the IR range.

43. The device of claim 33, wherein said non linear absorption is two-photon absorption.

44. The device of claim 33, wherein said electron-hole pair is generated by absorption of energy at the near IR and/or at the visible electromagnetic range.

45. A method of detection of electromagnetic radiation, said method comprising:
a. providing an electro-optical device comprising:
a grating comprising a slit array and a PN junction, a PIN junction or an avalanche photo diode, wherein said PN junction, said PIN junction or said avalanche photo diode is positioned on top of said grating, below said grating or on top and below said grating and wherein said PN junction, said PIN junction or said avalanche photo diode has no significant linear absorption at a certain wavelength range of the electromagnetic radiation spectrum;
b. connecting said PN junction, said PIN junction or said avalanche photo diode to a current meter;
c. irradiating said electro-optical device with electromagnetic radiation at said certain wavelength range such that said PN junction, said PIN junction or said avalanche photo diode generates electron-hole pairs upon non-linear absorption of said electromagnetic radiation at said wavelength range and wherein an electrical current is generated by said electron-hole pairs; and
d. using said current meter for detecting and/or measuring said current;
wherein upon said irradiation of said electro-optical device, the electromagnetic intensity within said PN junction, said PIN junction or said avalanche photo diode is enhanced resulting in amplification of a two-photon absorption process followed by amplified current generation by said PN junction, said PIN junction or said avalanche photo diode.

46. The method of claim 45, wherein said PN junction, a PIN junction or an avalanche photo diode is connected to a power supply.

47. The method of claim 46, wherein said power supply is used to apply voltage to said PN junction, a PIN junction or an avalanche photo diode.

48. The method of claim 45, wherein said PN junction, said PIN junction or said avalanche photo diode comprise GaAs, AlGaAs, Si, silicon dioxide, Quartz, Ge, GaN, GaAlN, InGaAs, InGaP or a combination thereof.

49. The method of claim 45, wherein a portion of said PN junction, said PIN junction or said avalanche photo diode is further positioned within said slits of said grating.

50. The method of claim 45, wherein said grating comprises an array of blocks separated by slits.

51. The method of claim 45, wherein the width of said blocks ranges between 400 nm and 600 nm.

52. The method of claim 45, wherein the height of said blocks ranges between 10 nm and 1500 nm.

53. The method of claim 45, wherein the width of said slits ranges between 100 nm and 750 nm.

54. The method of claim 45, wherein said certain wavelength range is within the IR range.

55. The method of claim 45, wherein said non linear absorption is two-photon absorption.

56. The method of claim 45, wherein said electron-hole pair is generated by absorption of electromagnetic radiation in the near IR range, in the visible range or a combination thereof.

57. The method of claim 45, wherein said irradiated electromagnetic radiation is broad-band.

58. The method of claim 57, wherein said broad-band ranges between 1000 nm and 2000 nm.

59. The method of claim 45, wherein said irradiated radiation, is polarized.

60. The method of claim 45, wherein the intensity of said absorbed radiation ranges between 10 and 100 times the intensity of said irradiated electromagnetic radiation.

61. A method of IR light sensing, said method comprising:
a. providing an electro-optical device comprising:
a grating comprising a slit array and a PN junction, a PIN junction or an avalanche photo diode, wherein said PN junction, said PIN junction or said avalanche photo diode is positioned on top of said grating, below said grating or on top and below said grating and wherein said PN junction, said PIN junction or said avalanche photo diode has no significant linear absorption at a certain wavelength range of the electromagnetic radiation spectrum, and wherein said PN junction, said PIN junction or said avalanche photo diode generates electron-hole pairs upon non-linear absorption of electromagnetic radiation at said wavelength range and wherein an electrical current is generated by said electron-hole pairs;
b. connecting said dielectric material to a current meter;
c. using said current meter for detecting and/or measuring current generated by said electro-optical device;
wherein upon IR sensing by said electro-optical device, the IR electromagnetic intensity within said PN junction, a PIN junction or an avalanche photo diode is enhanced resulting in amplification of IR two-photon absorption process within said PN junction, a PIN junction or an avalanche photo diode followed by amplified current generation by said PN junction, a PIN junction or an avalanche photo diode.

62. The method of claim 61, wherein said PN junction, a PIN junction or an avalanche photo diode is connected to a power supply.

63. The method of claim 62, wherein said power supply is used to apply voltage to said PN junction, a PIN junction or an avalanche photo diode.

64. The method of claim 61, wherein said IR light is generated by a laser, by a light emitting diode or by an object.

65. A method of IR imaging, said method comprising:
a. providing an array of electro-optical devices, wherein each electro-optical device comprising:
a grating comprising a slit array and a PN junction, a PIN junction or an avalanche photo diode, wherein said PN junction, said PIN junction or said avalanche photo diode is positioned on top of said grating, below said grating or on top and below said grating and wherein said PN junction, said PIN junction or said avalanche photo diode has no significant linear absorption at a certain wavelength range of the electromagnetic radiation spectrum, and wherein said PN junction, said PIN junction or said avalanche photo diode generates electron-hole pairs upon non-linear absorption of electromagnetic radiation at said wavelength range and wherein an electrical current is generated by said electron-hole pairs;
b. providing electrical current detectors such that each detector addresses one of said electro-optical devices;
c. using said current detectors for collecting and/or measuring current generated by each of said electro-optical devices; and
d. compiling an image from said current generated by each of said electro-optical devices.

66. The method of claim 65, wherein said PN junction, said PIN junction or said avalanche photo diode is connected to a power supply.

67. The method of claim 66, wherein said power supply is used to apply voltage to said PN junction, said PIN junction or said avalanche photo diode;

68. The method of claim 65, wherein said image is obtained using a computer.
